(19) United States
(12) Patent Application Publication
(10) Pub. No.: US 2023/0094400 A1
(43) Pub. Date: Mar. 30, 2023

(54) CAPACITOR STRUCTURE AND MANUFACTURING METHOD THEREOF

(71) Applicant: Powerchip Semiconductor Manufacturing Corporation, Hsinchu (TW)

(72) Inventors: Shih-Ping Lee, Hsinchu City (TW); Shih-Jan Tung, Hsinchu County (TW); Sz-Chi Li, New Taipei City (TW)

(73) Assignee: Powerchip Semiconductor Manufacturing Corporation, Hsinchu (TW)

(21) Appl. No.: 17/667,538

(22) Filed: Feb. 9, 2022

(30) Foreign Application Priority Data
Sep. 29, 2021 (TW) 110136193

(51) Int. Cl. H01L 23/522; H01L 49/02; H01L 21/768

(52) U.S. Cl. CPC H01L 23/5223; H01L 28/60; H01L 23/5226; H01L 21/76802; H01L 21/76877

(57) ABSTRACT

A capacitor structure including a substrate, at least one first dielectric layer, at least one second dielectric layer, a capacitor, and an interconnect structure is provided. The substrate includes a capacitor region and a non-capacitor region. The first dielectric layer is located in the capacitor region and the non-capacitor region. The second dielectric layer is located in the non-capacitor region. At least a portion of the second dielectric layer is located in the first dielectric layer. A material of the second dielectric layer is different from a material of at least a portion of the first dielectric layer. A dielectric constant of the second dielectric layer is smaller than a dielectric constant of at least a portion of the first dielectric layer. The capacitor is located in the first dielectric layer in the capacitor region. The interconnect structure is located in the second dielectric layer in the non-capacitor region.

### CROSS-REFERENCE TO RELATED APPLICATION

This application claims the priority benefit of Taiwanese application no. 110136193, filed on Sep. 29, 2021. The entirety of the above-mentioned patent application is hereby incorporated by reference herein and made a part of this specification.

### BACKGROUND OF THE INVENTION

### Field of the Invention

The invention relates to a semiconductor structure and a manufacturing method thereof, and particularly relates to a capacitor structure and a manufacturing method thereof.

### Description of Related Art

Currently, a capacitor structure has been developed that integrates the capacitor in the capacitor region with the interconnect structure in the logic device region. In addition, a low dielectric constant (low-k) dielectric layer is used as the dielectric layer in the logic device region to reduce the resistance-capacitance (RC) delay. However, when the low-k dielectric layer is used as the dielectric layer in the capacitor region, the capacitance value of the capacitor will be reduced. Therefore, it is necessary to increase the area of the capacitor to obtain a capacitor with the required capacitance value.

### SUMMARY OF THE INVENTION

The invention provides a capacitor structure and a manufacturing method thereof, which can increase the capacitance value of the capacitor in the capacitor region and simultaneously reduce the RC delay in the non-capacitor region.

The invention provides a capacitor structure, which includes a substrate, at least one first dielectric layer, at least one second dielectric layer, a capacitor, and an interconnect structure. The substrate includes a capacitor region and a non-capacitor region. The first dielectric layer is located on the substrate in the capacitor region and the non-capacitor region. The second dielectric layer is located on the substrate in the non-capacitor region. At least a portion of the second dielectric layer is located in the first dielectric layer. A material of the second dielectric layer is different from a material of at least a portion of the first dielectric layer. A dielectric constant of the second dielectric layer is smaller than a dielectric constant of at least a portion of the first dielectric layer. The capacitor is located in the at least one first dielectric layer in the capacitor region. The capacitor includes two electrodes electrically insulated from each other. The interconnect structure is located in the at least one second dielectric layer in the non-capacitor region.

According to an embodiment of the invention, in the capacitor structure, the material of the second dielectric layer may be completely different from the material of the first dielectric layer.

According to an embodiment of the invention, in the capacitor structure, the dielectric constant of the second dielectric layer may be smaller than the dielectric constant of the entire first dielectric layer.

According to an embodiment of the invention, in the capacitor structure, the entire second dielectric layer may be located in the first dielectric layer.

According to an embodiment of the invention, in the capacitor structure, the electrode may include at least one first conductive structure. The first conductive structure may include first conductive layer. The interconnect structure may include at least one second conductive structure. The second conductive structure may include a second conductive layer.

According to an embodiment of the invention, in the capacitor structure, each of the first conductive structure and the second conductive structure may include a dual damascene structure or a single damascene structure.

According to an embodiment of the invention, in the capacitor structure, a bottom surface of the second conductive layer may be lower than a bottom surface of the first conductive layer.

According to an embodiment of the invention, in the capacitor structure, a bottom surface of the second conductive layer may be the same height as a bottom surface of the first conductive layer.

According to an embodiment of the invention, in the capacitor structure, the first conductive structure may further include a first conductive via. The first conductive via is located under the first conductive layer and is electrically connected to the first conductive layer. The second conductive structure may further include a second conductive via. The second conductive via is located under the second conductive layer and is electrically connected to the second conductive layer.

According to an embodiment of the invention, in the capacitor structure, the first conductive layer and the first conductive via may be integrally formed. The second conductive layer and second conductive via may be integrally formed.

According to an embodiment of the invention, in the capacitor structure, the first conductive layer and the first conductive via may be components independent of each other. The second conductive layer and the second conductive via may be components independent of each other.

According to an embodiment of the invention, in the capacitor structure, each of the first dielectric layer and the second dielectric layer may be a single-layer structure.

According to an embodiment of the invention, in the capacitor structure, each of the first dielectric layer and the second dielectric layer may be a multilayer structure.

According to an embodiment of the invention, in the capacitor structure, the first dielectric layer may include a first dielectric material layer and a second dielectric material layer. The first conductive via is located in the first dielectric material layer. The second dielectric material layer is located on the first dielectric material layer. The first conductive layer is located in the second dielectric material layer. The second dielectric layer may include a third dielectric material layer and a fourth dielectric material layer. The third dielectric material layer is located in the first dielectric material layer. The second conductive via is located in the third dielectric material layer. The fourth dielectric material layer is located on the third dielectric material layer. The fourth dielectric material layer is located in the second dielectric material layer. The second conductive layer is located in the fourth dielectric material layer.

According to an embodiment of the invention, in the capacitor structure, the first dielectric layer may include a first dielectric material layer and a second dielectric material layer. The first conductive via is located in the first dielectric material layer. The second dielectric material layer is located on the first dielectric material layer. The first conductive layer is located in the second dielectric material layer. The second dielectric layer may include the first dielectric material layer and a third dielectric material layer. The second conductive via is located in the first dielectric material layer. The third dielectric material layer is located on the first dielectric material layer. The third dielectric material layer is located in the second dielectric material layer. The second conductive layer is located in the third dielectric material layer.

According to an embodiment of the invention, in the capacitor structure, the first dielectric layer may include a first dielectric material layer and a second dielectric material layer. The first conductive via is located in the first dielectric material layer. The second dielectric material layer is located on the first dielectric material layer. The first conductive layer is located in the second dielectric material layer. The second dielectric layer may include a third dielectric material layer and the second dielectric material layer. The third dielectric material layer is located in the first dielectric material layer. The second conductive via is located in the third dielectric material layer. The second dielectric material layer is located on the third dielectric material layer. The second conductive layer is located in the second dielectric material layer.

According to an embodiment of the invention, in the capacitor structure, the electrode may include a plurality of the first conductive structures electrically connected to each other. The interconnect structure may include a plurality of the second conductive structures electrically connected to each other.

The invention provides a manufacturing method of a capacitor structure, which includes the following steps. A substrate is provided. The substrate includes a capacitor region and a non-capacitor region. At least one first dielectric layer is formed on the substrate in the capacitor region and the non-capacitor region. At least one second dielectric layer is formed on the substrate in the non-capacitor region. At least a portion of the second dielectric layer is located in the first dielectric layer. A material of the second dielectric layer is different from a material of at least a portion of the first dielectric layer. A dielectric constant of the second dielectric layer is smaller than a dielectric constant of at least a portion of the first dielectric layer. A capacitor is formed in the at least one first dielectric layer in the capacitor region. The capacitor includes two electrodes electrically insulated from each other. An interconnect structure is formed in the at least one second dielectric layer in the non-capacitor region.

According to an embodiment of the invention, in the manufacturing method of the capacitor structure, the electrode may include at least one first conductive structure. The interconnect structure may include at least one second conductive structure. A method of forming the first conductive structure and the second conductive structure may include the following steps. The first dielectric layer is formed on the substrate. An opening is formed in the first dielectric layer. A dielectric material layer filling up the opening is formed. The dielectric material layer located outside the opening is removed to form the second dielectric layer. The first conductive structure is formed in the first dielectric layer and the second conductive structure is formed in the second dielectric layer by a damascene process.

According to an embodiment of the invention, in the manufacturing method of the capacitor structure, the damascene process may be a dual damascene process or a single damascene process.

Based on the above description, in the capacitor structure and the manufacturing method according to the invention, the material of the second dielectric layer is different from the material of at least a portion of the first dielectric layer, and the dielectric constant of the second dielectric layer is smaller than the dielectric constant of at least a portion of the first dielectric layer. Since at least a portion of the first dielectric layer in the capacitor region has a higher dielectric constant, the capacitance value of the capacitor in the capacitor region can be increased, thereby reducing the area of the capacitor. In addition, since the second dielectric layer in the non-capacitor region has a lower dielectric constant, the parasitic capacitance can be reduced, thereby reducing the RC delay in the non-capacitor region.

In order to make the aforementioned and other objects, features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1A to FIG. 1F are cross-sectional views illustrating a manufacturing process of a capacitor structure according to some embodiments of the invention.

FIG. 2 is a cross-sectional view illustrating a capacitor structure according to another embodiments of the invention.

FIG. 3 is a cross-sectional view illustrating a capacitor structure according to another embodiments of the invention.

FIG. 4 is a cross-sectional view illustrating a capacitor structure according to another embodiments of the invention.

FIG. 5 is a cross-sectional view illustrating a capacitor structure according to another embodiments of the invention.

FIG. 6 is a cross-sectional view illustrating a capacitor structure according to another embodiments of the invention.

FIG. 7 is a cross-sectional view illustrating a capacitor structure according to another embodiments of the invention.

FIG. 8 is a cross-sectional view illustrating a capacitor structure according to another embodiments of the invention.

FIG. 9 is a cross-sectional view illustrating a capacitor structure according to another embodiments of the invention.

### DESCRIPTION OF THE EMBODIMENTS

The embodiments are described in detail below with reference to the accompanying drawings, but the embodiments are not intended to limit the scope of the present invention. In addition, for the sake of easy understanding, the same components in the following description will be denoted by the same reference symbols.

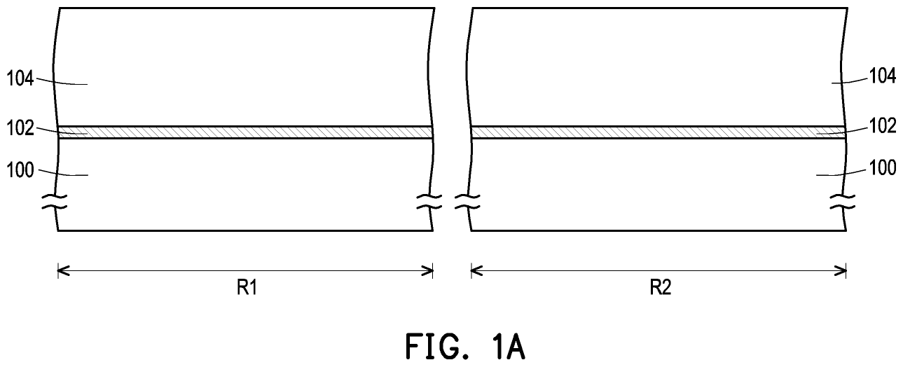

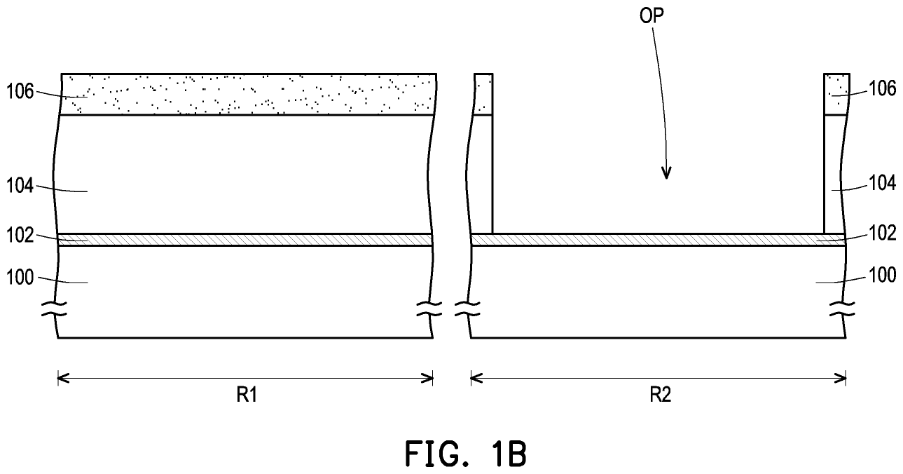

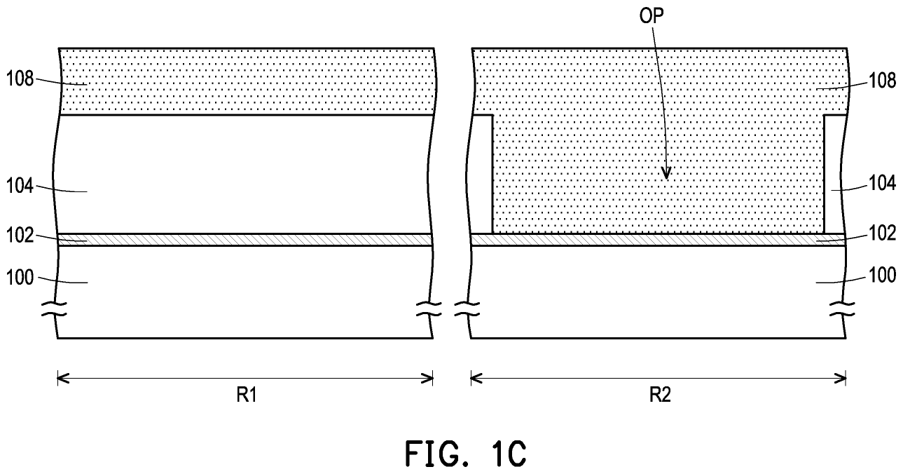

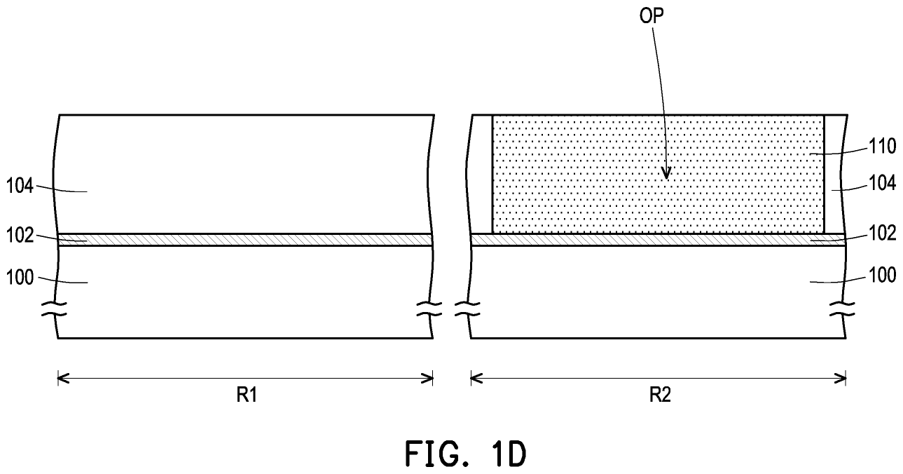

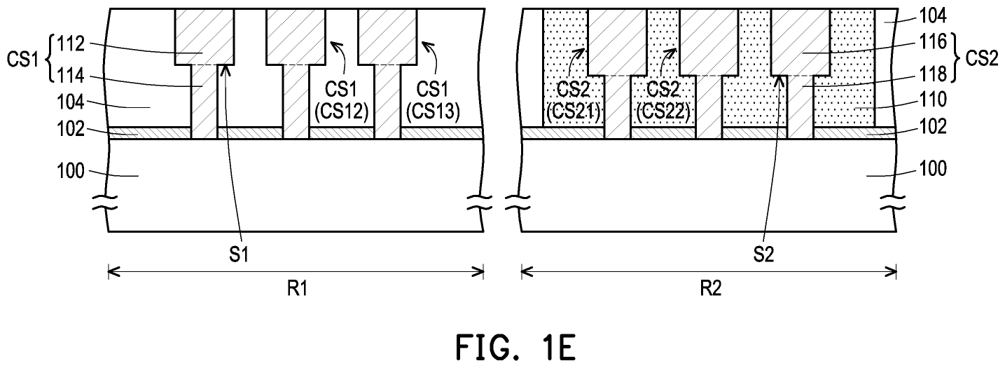

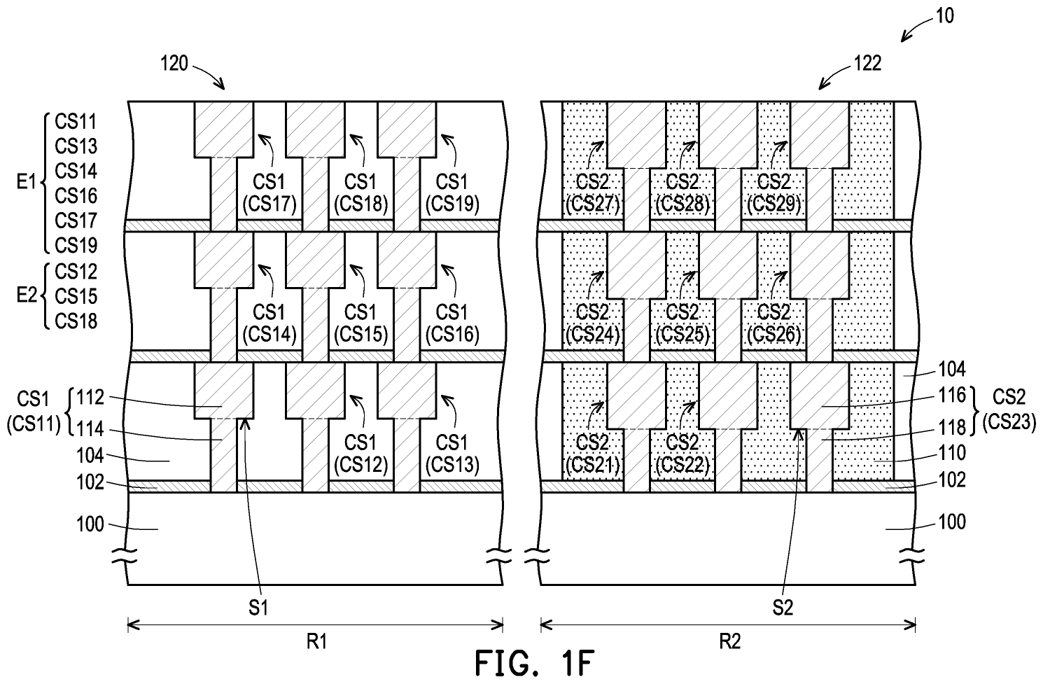

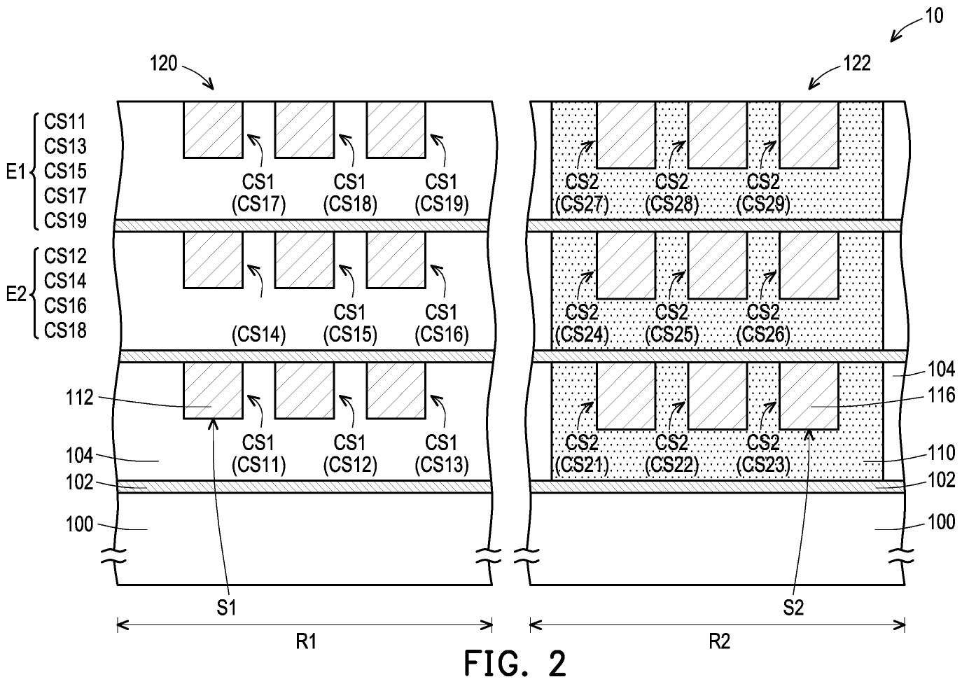

FIG. 1A to FIG. 1F are cross-sectional views illustrating a manufacturing process of a capacitor structure according to some embodiments of the invention. FIG. 2 is a cross-sectional view illustrating a capacitor structure according to another embodiments of the invention.

Referring to FIG. 1A, a substrate 100 is provided. The substrate 100 may be a semiconductor substrate such as a silicon substrate. The substrate 100 includes a capacitor region R1 and a non-capacitor region R2. The capacitor region R1 is a region for forming a capacitor (e.g., metal-oxide-metal (MOM) capacitor). In some embodiments, the non-capacitor region R2 may be a logic device region, but the invention is not limited thereto. Throughout the description, the term “MOM capacitor” is used to refer to a capacitor that has an insulator between two conductive layers, wherein although the insulator may be oxide, the insulator may also be a dielectric material other than oxide. In addition, although not shown in FIG. 1A, there may be some required components such as the doped region and/or the isolation structure in the substrate 100, there may be some required components such as the semiconductor device (e.g., the active device and/or the passive device), the dielectric layer, and the interconnect structure on the substrate 100, and the description thereof is omitted here.

A stop layer 102 may be formed on the substrate 100. The material of the stop layer 102 is, for example, silicon carbonitride (SiCN) or silicon nitride (SiN). The method of forming the stop layer 102 is, for example, a chemical vapor deposition method.

A dielectric layer 104 is formed on the substrate 100 in the capacitor region R1 and the non-capacitor region R2. For example, the dielectric layer 104 may be formed on the stop layer 102. In the present embodiment, the dielectric layer 104 may be a single-layer structure, but the invention is not limited thereto. In other embodiments, the dielectric layer 104 may be a multilayer structure. The material of the dielectric layer 104 is, for example, silicon oxide, but the invention is not limited thereto.

Referring to FIG. 1B, a patterned photoresist layer 106 may be formed on the dielectric layer 104. The patterned photoresist layer 106 may be formed by a lithography process. A portion of the dielectric layer 104 may be removed by using the patterned photoresist layer 106 as a mask. In this way, an opening OP may be formed in the dielectric layer 104. The method of removing the portion of the dielectric layer 104 is, for example, a dry etching method.

Referring to FIG. 1C, the patterned photoresist layer 106 may be removed. The method of removing the patterned photoresist layer 106 is, for example, a dry stripping method or a wet stripping method.

A dielectric material layer 108 filling up the opening OP may be formed. The method of forming the dielectric material layer 108 is, for example, a spin coating method or a chemical vapor deposition method. The material of the dielectric material layer 108 is different from the material of the dielectric layer 104. The dielectric constant of the dielectric material layer 108 is smaller than the dielectric constant of the dielectric layer 104. The material of the dielectric material layer 108 is, for example, a low dielectric constant (low-k) material such as an oxide derivative, an organic compound, or a highly porous oxide. The oxide derivative is, for example, fluorine-doped oxide (F-doped oxide), carbon-doped oxide (C-doped oxide), or hydrogen-doped oxide (H-doped oxide). The organic compound is, for example, polyimide, aromatic polymer, vapor-deposited parylene, fluorine-doped amorphous carbon (F-doped amorphous carbon), or polytetrafluoroethylene (PTFE). The highly porous oxide is, for example, xerogel or aerogel.

Referring to FIG. 1D, the dielectric material layer 108 located outside the opening OP may be removed to form a dielectric layer 110. In the present embodiment, the entire dielectric layer 110 may be located in the dielectric layer 104. The method of removing the dielectric material layer 108 located outside the opening OP is, for example, a chemical mechanical polishing method. In the present embodiment, the dielectric layer 110 may be a single-layer structure, but the invention is not limited thereto. In other embodiments, the dielectric layer 110 may be a multilayer structure. The material of the dielectric layer 110 may refer to the description of the material of the dielectric material layer 108, and the description thereof is omitted here.

Referring to FIG. 1E, a conductive structure CS1 may be formed in the dielectric layer 104 and a conductive structure CS2 may be formed in the dielectric layer 110 by a damascene process. The conductive structure CS1 and the conductive structure CS2 may pass through the stop layer 102. The conductive structure CS1 and the conductive structure CS2 may be simultaneously formed by a damascene process. In the present embodiment, the damascene process may be a dual damascene process, and each of the conductive structure CS1 and the conductive structure CS2 may include a dual damascene structure, but the invention is not limited thereto. The dual damascene process is, for example, a via-first dual damascene process, a trench-first dual damascene process, a self-aligned dual damascene process, or a top hard mask dual damascene process. Furthermore, the structure formed by different dual damascene processes may be slightly different. The materials of the conductive structure CS1 and the conductive structure CS2 are, for example, copper.

The conductive structure CS1 may include a conductive layer 112. The conductive layer 112 may be a conductive line. Moreover, the conductive structure CS1 may further include a conductive via 114. The conductive via 114 is located under the conductive layer 112 and is electrically connected to the conductive layer 112. In the present embodiment, the conductive layer 112 and the conductive via 114 may be integrally formed. In some embodiments, a barrier layer (not shown) may be formed between the conductive layer 112 and the dielectric layer 104, between the conductive via 114 and the dielectric layer 104, between the conductive via 114 and the stop layer 102, and between the conductive via 114 and the substrate 100, and the description thereof is omitted here.

The conductive structure CS2 may include a conductive layer 116. The conductive layer 116 may be a conductive line. In the present embodiment, since the etching process in the damascene process has a higher etching rate on the dielectric layer 110 than on the dielectric layer 104, the bottom surface S2 of the conductive layer 116 may be lower than the bottom surface S1 of the conductive layer 112, but the invention is not limited thereto. In addition, the conductive structure CS2 may further include a conductive via 118. The conductive via 118 is located under the conductive layer 116 and is electrically connected to the conductive layer 116. In the present embodiment, the conductive layer 116 and the conductive via 118 may be integrally formed. In some embodiments, a barrier layer (not shown) may be formed between the conductive layer 116 and the dielectric layer 110, between the conductive via 118 and the dielectric layer 110, between the conductive via 118 and the stop layer 102, and between the conductive via 118 and the substrate 100, and the description thereof is omitted here.

Referring to FIG. 1F, the steps of FIG. 1A to FIG. 1E may be repeated (but the step of providing the substrate 100 is not repeated), whereby a plurality of the conductive structures CS1 electrically connected to each other and a plurality of the conductive structures CS2 electrically connected to each other may be formed.

Furthermore, by the above method, at least one dielectric layer 104 may be formed on the substrate 100 in the capacitor region R1 and the non-capacitor region R2, at least one dielectric layer 110 may be formed on the substrate 100 in the non-capacitor region R2, a capacitor 120 may formed in the at least one dielectric layer 104 in the capacitor region R1, and an interconnect structure 122 may be formed in the at least one dielectric layer 110 in the non-capacitor region R2. In this way, the capacitor structure 10 may be formed. In other embodiments, according to the design of capacitor structure 10, the step of FIG. 1F may be omitted.

Hereinafter, the capacitor structure 10 of the above embodiment is described with reference to FIG. 1F. Moreover, although the method for forming the capacitor structure 10 is described by taking the above method as an example, the invention is not limited thereto.

Referring to FIG. 1F, the capacitor structure 10 includes a substrate 100, at least one dielectric layer 104, at least one dielectric layer 110, a capacitor 120, and an interconnect structure 122. The capacitor structure 10 may be a MOM capacitor. In the present embodiment, the number of dielectric layers 104 is, for example, multiple, and the number of dielectric layers 110 is, for example, multiple, but the invention is not limited thereto. The substrate 100 includes a capacitor region R1 and a non-capacitor region R2. The dielectric layer 104 is located on the substrate 100 in the capacitor region R1 and the non-capacitor region R2. The dielectric layer 110 is located on the substrate 100 in the non-capacitor region R2. At least a portion of the dielectric layer 110 is located in the dielectric layer 104. The material of the dielectric layer 110 is different from the material of at least a portion of the dielectric layer 104. In the present embodiment, the material of the dielectric layer 110 may be completely different from the material of the dielectric layer 104. The dielectric constant of the dielectric layer 110 is smaller than the dielectric constant of at least a portion of the dielectric layer 104. In the present embodiment, the dielectric constant of the dielectric layer 110 may be smaller than the dielectric constant of the entire dielectric layer 104. The capacitor 120 is located in at least one dielectric layer 104 in the capacitor region R1. The capacitor 120 includes two electrodes (e.g., the electrode E1 and the electrode E2) electrically insulated from each other. Furthermore, the capacitor 120 may further include the dielectric layer 104 located between the electrode E1 and the electrode E2. The interconnect structure 122 is located in at least one dielectric layer 110 in the non-capacitor region R2.

Moreover, the capacitor structure 10 may further include at least one stop layer 102. In the present embodiment, the number of stop layers 102 is, for example, multiple, but the invention is not limited thereto. The dielectric layer 104 and the dielectric layer 110 may be located on the corresponding stop layer 102. The conductive via 114 of the conductive structure CS1 and the conductive via 118 of the conductive structure CS2 may pass through the corresponding stop layer 102.

Each of the electrode E1 and the electrode E2 may include at least one conductive structure CS1. In the present embodiment, the electrode E1 may include a plurality of conductive structures CS1 electrically connected to each other, and the electrode E2 may include a plurality of conductive structures CS1 electrically connected to each other, but the invention is not limited thereto. As long as each of the electrode E1 and the electrode E2 includes at least one conductive structure CS1, it belongs to the scope of the invention. For example, the electrode E1 may include the conductive structure CS11, the conductive structure CS13, the conductive structure CS14, the conductive structure CS16, the conductive structure CS17, and the conductive structure CS19 electrically connected to each other, and the electrode E2 may include the conductive structure CS12, the conductive structure CS15, and the conductive structure CS18 electrically connected to each other, but the invention is not limited thereto. The conductive structure CS11, the conductive structure CS13, the conductive structure CS14, the conductive structure CS16, the conductive structure CS17, and the conductive structure CS19 may be electrically connected according to the interconnect routing design, the conductive structure CS12, the conductive structure CS15, and the conductive structure CS18 may be electrically connected according to the interconnect routing design, and the description thereof is omitted here.

In the present embodiment, in the capacitor 120, although a plurality of the conductive structures CS1 electrically connected to each other (e.g., the conductive structure CS11, the conductive structure CS14, and the conductive structure CS17 electrically connected to each other) may be located in the same cross-sectional view, the invention is not limited thereto. For example, in some cross-sectional views, only the conductive layer 112 of the conductive structure CS17 can be seen, but the conductive via 114 of the conductive structure CS17 and the conductive structure CS14 and the conductive structure CS11 that are electrically connected to the conductive structure CS17 cannot be seen. In some cross-sectional views, only the conductive structure CS17 and the conductive layer 112 of the conductive structure CS14 can be seen, but the conductive via 114 of the conductive structure CS14 and the conductive structure CS11 that is electrically connected to the conductive structure CS14 cannot be seen.

The number and configuration of the conductive structure CS1 of the electrode E1 and the number and configuration of the conductive structure CS1 of the electrode E2 may be flexibly adjusted according to the interconnect routing design of the electrode E1 and the electrode E2. As long as the electrode E1 and the electrode E2 are electrically insulated from each other, and the conductive structure CS1 of the electrode E1 and the conductive structure CS1 of the electrode E2 are adjacent to each other and are electrically connected to different voltage sources, it belongs to the scope of the invention. In other embodiments, as shown in FIG. 2, the interconnect routing design of the electrode E1 and the electrode E2 in FIG. 2 is different from the interconnect routing design of the electrode E1 and the electrode E2 in FIG. 1. For example, the electrode E1 in FIG. 2 may include the conductive structure CS11, the conductive structure CS13, the conductive structure CS15, the conductive structure CS17, and the conductive structure CS19 electrically connected to each other, the electrode E2 in FIG. 2 may include the conductive structure CS12, the conductive structure CS14, the conductive structure CS16, and the conductive structure CS18 electrically connected to each other, and the electrode E1 and the electrode E2 in FIG. 2 are electrically insulated from each other. In the embodiment of FIG. 2, the conductive structure CS11, the conductive structure CS13, the conductive structure CS15, the conductive structure CS17, and the conductive structure CS19 may be electrically connected according to the interconnect routing design, the conductive structure CS12, the conductive structure CS14, the conductive structure CS16, and the conductive structure CS18 may be electrically connected according to the interconnect routing design, and the description thereof is omitted here. According to the interconnect routing design of the embodiment of FIG. 2, the conductive via 114 of the conductive structure CS1 cannot be seen in the cross-sectional view of FIG. 2, so the conductive via 114 of the conductive structure CS1 is not shown in FIG. 2.

Referring to FIG. 1F, the interconnect structure 122 may include at least one conductive structure CS2. The interconnect structure 122 may include a plurality of the conductive structures CS2 electrically connected to each other. For example, the conductive structure CS21, the conductive structure CS24, and the conductive structure CS27 may be electrically connected to each other and may be electrically connected to the corresponding semiconductor device and/or voltage source. The conductive structure CS22, the conductive structure CS25, and the conductive structure CS28 may be electrically connected to each other and may be electrically connected to the corresponding semiconductor device and/or voltage source. The conductive structure CS23, the conductive structure CS26, and the conductive structure CS29 may be electrically connected to each other and may be electrically connected to the corresponding semiconductor device and/or voltage source. In addition, the number and configuration of the conductive structure CS2 of the interconnect structure 122 may be flexibly adjusted according to the interconnect routing design of the interconnect structure 122.

Furthermore, in the interconnect structure 122, although a plurality of the conductive structures CS2 electrically connected to each other (e.g., the conductive structure CS21, the conductive structure CS24, and the conductive structure CS27 electrically connected to each other) may be located in the same cross-sectional view, the invention is not limited thereto. For example, in some cross-sectional views, only the conductive layer 116 of the conductive structure CS27 can be seen, but the conductive via 118 of the conductive structure CS27 and the conductive structure CS24 and the conductive structure CS21 that are electrically connected to the conductive structure CS27 cannot be seen. In some cross-sectional views, only the conductive structure CS27 and the conductive layer 116 of the conductive structure CS24 can be seen, but the conductive via 118 of the conductive structure CS24 and the conductive structure CS21 that is electrically connected to the conductive structure CS24 cannot be seen.

In addition, the material, the forming method, and the effect of each component in the capacitor structure 10 have been described in detail in the above embodiments, and the description thereof is not repeated here.

Based on the above embodiments, in the capacitor structure 10 and the manufacturing method thereof, the material of the dielectric layer 110 is different from the material of at least a portion of the dielectric layer 104, and the dielectric constant of the dielectric layer 110 is smaller than the dielectric constant of at least a portion of the dielectric layer 104. Since at least a portion of the dielectric layer 104 in the capacitor region R1 has a higher dielectric constant, the capacitance value of the capacitor 120 in the capacitor region R1 can be increased, thereby reducing the area of the capacitor 120. In addition, since the dielectric layer 110 in the non-capacitor region R2 has a lower dielectric constant, the parasitic capacitance can be reduced, thereby reducing the RC delay in the non-capacitor region R2.

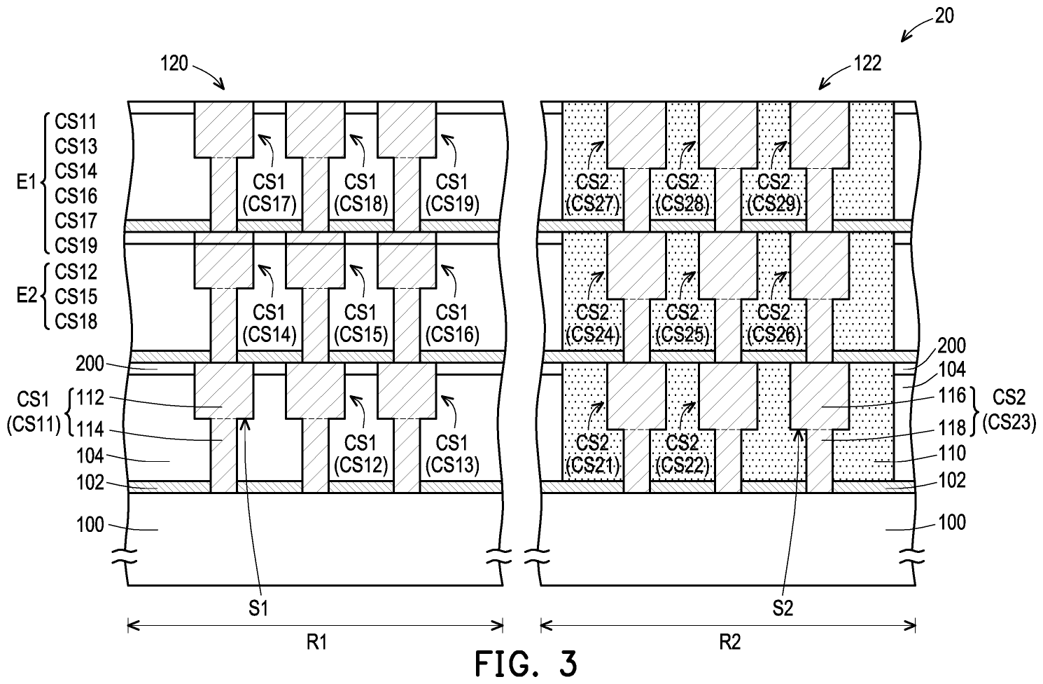

FIG. 3 is a cross-sectional view illustrating a capacitor structure according to another embodiments of the invention.

Referring to FIG. 1F and FIG. 3, the difference between the capacitor structure 20 in FIG. 3 and the capacitor structure 10 in FIG. 1F is as follows. In FIG. 3, the capacitor structure 20 may further include a stop layer 200. The stop layer 200 is located on the corresponding dielectric layer 104 and the corresponding dielectric layer 110, and a portion of the conductive structure CS1 and a portion of the conductive structure CS2 may be located in the stop layer 200. In the process for forming the dielectric layer 110, the stop layer 200 may be used as a polishing stop layer. The material of the stop layer 200 is, for example, silicon carbonitride or silicon nitride.

In addition, the same components in the capacitor structure 20 and the capacitor structure 10 are denoted by the same reference symbols, the same or similar content in the capacitor structure 20 and the capacitor structure 10 may refer to the description of the capacitor structure 10 in the foregoing embodiments, and the description thereof is omitted.

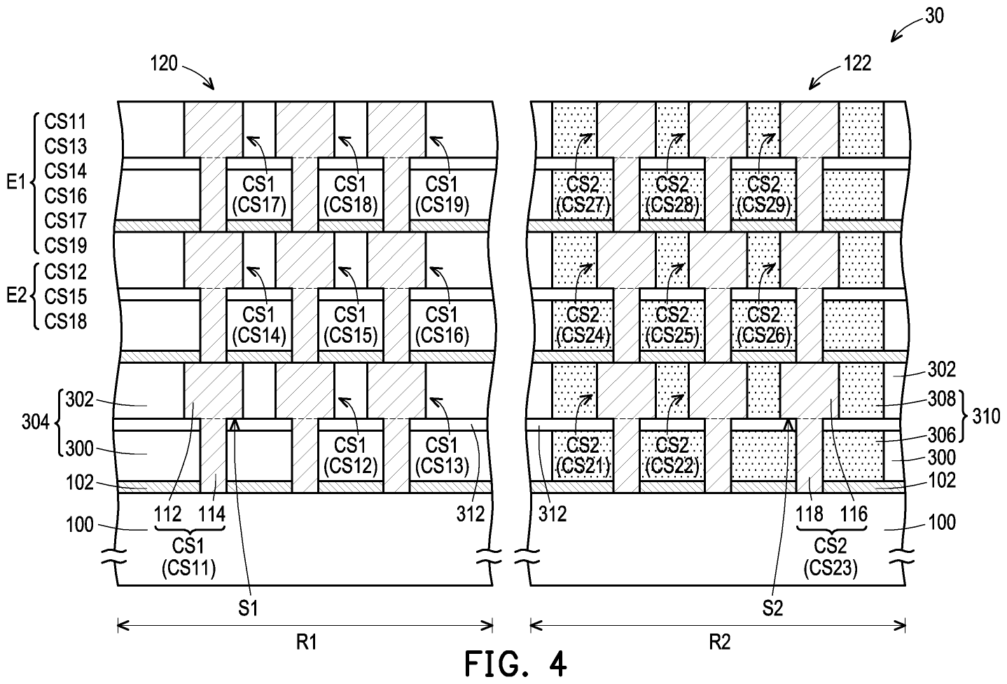

FIG. 4 is a cross-sectional view illustrating a capacitor structure according to another embodiments of the invention.

Referring to FIG. 1F and FIG. 4, the difference between the capacitor structure 30 in FIG. 4 and the capacitor structure 10 in FIG. 1F is as follows. In the capacitor structure 30 of FIG. 4, each of the dielectric layer 304 and the dielectric layer 310 may be a multilayer structure. The dielectric layer 304 may include a dielectric material layer 300 and a dielectric material layer 302. The conductive via 114 is located in the dielectric material layer 300. The dielectric material layer 302 is located on the dielectric material layer 300. The conductive layer 112 is located in the dielectric material layer 302. The material of the dielectric material layer 300 and the material of the dielectric material layer 302 are, for example, silicon oxide. The dielectric layer 310 may include a dielectric material layer 306 and a dielectric material layer 308. The dielectric material layer 306 is located in the dielectric material layer 300. The conductive via 118 is located in the dielectric material layer 306. The dielectric material layer 308 is located on the dielectric material layer 306. The dielectric material layer 308 is located in the dielectric material layer 302. The conductive layer 116 is located in the dielectric material layer 308. The material of the dielectric material layer 306 and the material of the dielectric material layer 308 are, for example, low-k materials. The material of the dielectric material layer 306 and the material of the dielectric material layer 308 may refer to the description of the material of the dielectric material layer 108, and the description thereof is omitted here. The material of the dielectric material layer 306 and the material of the dielectric material layer 308 are different from the material of the dielectric material layer 300 and the material of the dielectric material layer 302, so that the material of the dielectric layer 310 may be completely different from the material of the dielectric layer 304. The dielectric constant of the dielectric material layer 306 and the dielectric constant of the dielectric material layer 308 are smaller than the dielectric constant of the dielectric material layer 300 and the dielectric constant of the dielectric material layer 302, so that the dielectric constant of the dielectric layer 310 may be smaller than the dielectric constant of the entire dielectric layer 304.

In addition, the method for forming the dielectric material layer 306 and the dielectric material layer 308 may refer to the method for forming the dielectric layer 110 in FIG. 1A to FIG. 1D, and the description thereof is omitted here. In other embodiments, the stop layer 200 in FIG. 3 may be applied to the manufacturing process of the dielectric material layer 306 and the dielectric material layer 308.

Furthermore, the capacitor structure 30 may further include a stop layer 312. The stop layer 312 is located between the dielectric material layer 300 and the dielectric material layer 302 and between the dielectric material layer 306 and the dielectric material layer 308. The material of the stop layer 312 is, for example, silicon carbonitride or silicon nitride. In the capacitor structure 30 of FIG. 4, the bottom surface S2 of the conductive layer 116 may be the same height as the bottom surface S1 of the conductive layer 112.

Moreover, the same components in the capacitor structure 30 and the capacitor structure 10 are denoted by the same reference symbols, the same or similar content in the capacitor structure 30 and the capacitor structure 10 may refer to the description of the capacitor structure 10 in the foregoing embodiments, and the description thereof is omitted.

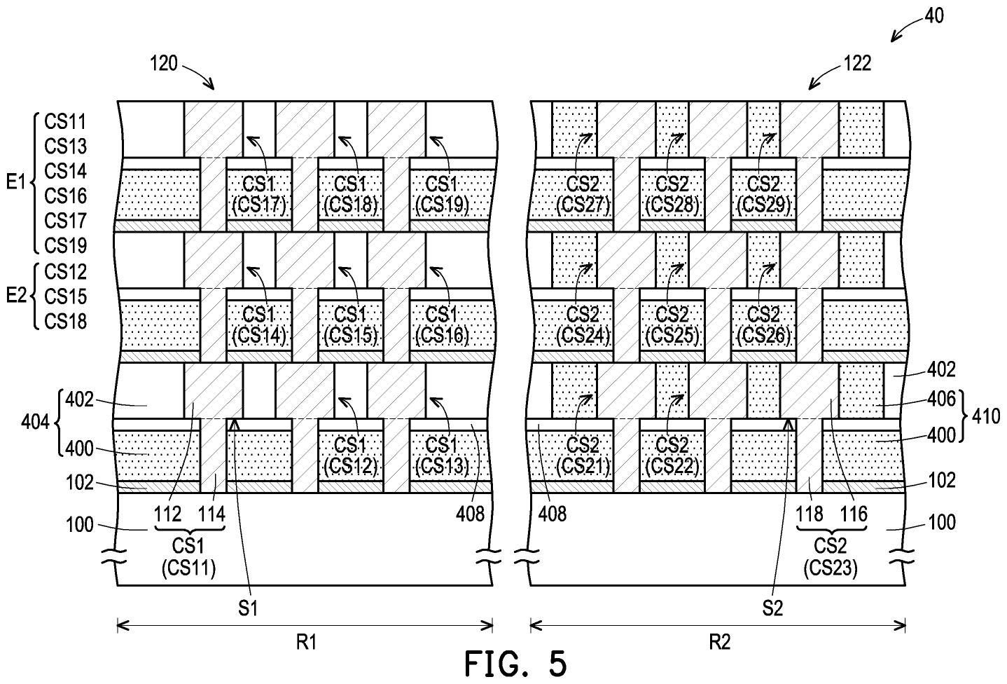

FIG. 5 is a cross-sectional view illustrating a capacitor structure according to another embodiments of the invention.

Referring to FIG. 1F and FIG. 5, the difference between the capacitor structure 40 in FIG. 5 and the capacitor structure 10 in FIG. 1F is as follows. In the capacitor structure 40 of FIG. 5, each of the dielectric layer 404 and the dielectric layer 410 may be a multilayer structure. The dielectric layer 404 may include a dielectric material layer 400 and a dielectric material layer 402. The conductive via 114 is located in the dielectric material layer 400. The material of the dielectric material layer 400 is, for example, a low-k material. The material of the dielectric material layer 400 may refer to the description of the material of the dielectric material layer 108, and the description is omitted here. The dielectric material layer 402 is located on the dielectric material layer 400. The conductive layer 112 is located in the dielectric material layer 402. The material of the dielectric material layer 402 is, for example, silicon oxide. The dielectric layer 410 may include the dielectric material layer 400 and a dielectric material layer 406. The conductive via 118 is located in the dielectric material layer 400. The dielectric material layer 406 is located on the dielectric material layer 400. The dielectric material layer 406 is located in the dielectric material layer 402. The conductive layer 116 is located in the dielectric material layer 406. The material of the dielectric material layer 406 is, for example, a low-k material. The material of the dielectric material layer 406 may refer to the description of the material of the dielectric material layer 108, and the description is omitted here. In addition, the material of the dielectric material layer 406 is different from the material of the dielectric material layer 402, so that the material of the dielectric layer 410 is different from the material of at least a portion of the dielectric layer 404. Furthermore, the dielectric constant of the dielectric material layer 406 is smaller than the dielectric constant of the dielectric material layer 402, so that the dielectric constant of the dielectric layer 410 is smaller than the dielectric constant of at least a portion of the dielectric layer 404.

Moreover, the method for forming the dielectric material layer 406 may refer to the method for forming the dielectric layer 110 in FIG. 1A to FIG. 1D, and the description thereof is omitted here. In other embodiments, the stop layer 200 in FIG. 3 may be applied to the manufacturing process of the dielectric material layer 406.

In addition, the capacitor structure 40 may further include a stop layer 408. The stop layer 408 is located between the dielectric material layer 400 and the dielectric material layer 402 and between the dielectric material layer 400 and the dielectric material layer 406. The material of the stop layer 408 is, for example, silicon carbonitride or silicon nitride. In the capacitor structure 40 of FIG. 5, the bottom surface S2 of the conductive layer 116 may be the same height as the bottom surface S1 of the conductive layer 112.

Moreover, the same components in the capacitor structure 40 and the capacitor structure 10 are denoted by the same reference symbols, the same or similar content in the capacitor structure 40 and the capacitor structure 10 may refer to the description of the capacitor structure 10 in the foregoing embodiments, and the description thereof is omitted.

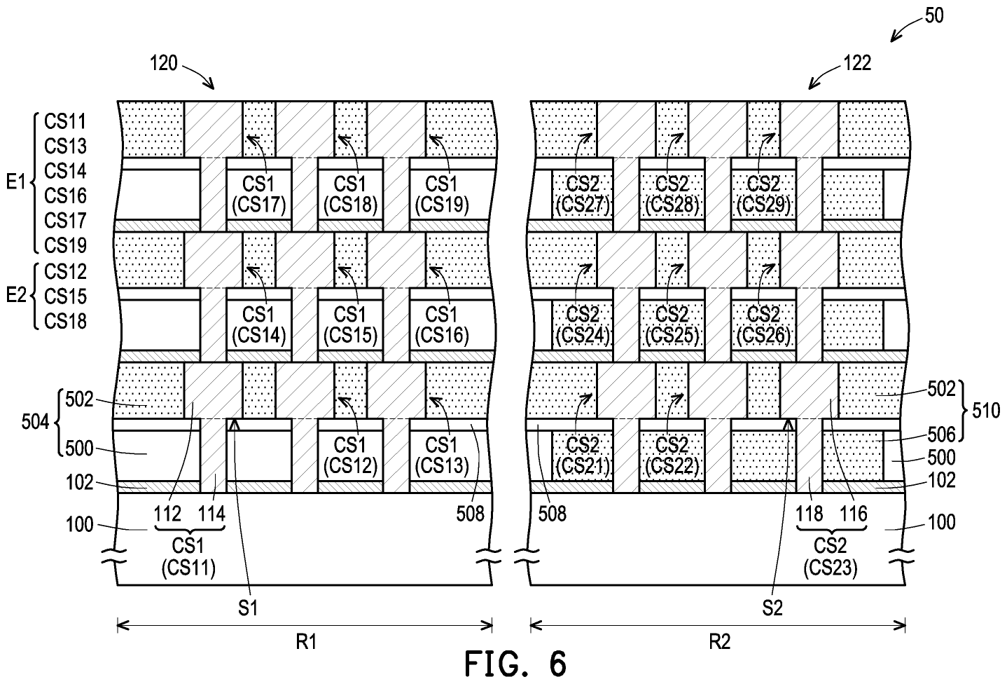

FIG. 6 is a cross-sectional view illustrating a capacitor structure according to another embodiments of the invention.

Referring to FIG. 1F and FIG. 6, the difference between the capacitor structure 50 in FIG. 6 and the capacitor structure 10 in FIG. 1F is as follows. In the capacitor structure 50 of FIG. 6, each of the dielectric layer 504 and the dielectric layer 510 may be a multilayer structure. The dielectric layer 504 may include a dielectric material layer 500 and a dielectric material layer 502. The conductive via 114 is located in the dielectric material layer 500. The material of the dielectric material layer 500 is, for example, silicon oxide. The dielectric material layer 502 is located on the dielectric material layer 500. The conductive layer 112 is located in the dielectric material layer 502. The material of the dielectric material layer 502 is, for example, a low-k material. The material of the dielectric material layer 502 may refer to the description of the material of the dielectric material layer 108, and the description is omitted here. The dielectric layer 510 may include a dielectric material layer 506 and the dielectric material layer 502. The dielectric material layer 506 is located in the dielectric material layer 500. The conductive via 118 is located in the dielectric material layer 506. The material of the dielectric material layer 506 is, for example, a low-k material. The material of the dielectric material layer 506 may refer to the description of the material of the dielectric material layer 108, and the description is omitted here. The dielectric material layer 502 is located on the dielectric material layer 506. The conductive layer 116 is located in the dielectric material layer 502. In addition, the material of the dielectric material layer 506 is different from the material of the dielectric material layer 500, so that the material of the dielectric layer 510 is different from the material of at least a portion of the dielectric layer 504. Furthermore, the dielectric constant of the dielectric material layer 506 is smaller than the dielectric constant of the dielectric material layer 500, so that the dielectric constant of the dielectric layer 510 is smaller than the dielectric constant of at least a portion of the dielectric layer 504.

Moreover, the method for forming the dielectric material layer 506 may refer to the method for forming the dielectric layer 110 in FIG. 1A to FIG. 1D, and the description thereof is omitted here. In other embodiments, the stop layer 200 in FIG. 3 may be applied to the manufacturing process of the dielectric material layer 506.

In addition, the capacitor structure 50 may further include a stop layer 508. The stop layer 508 is located between the dielectric material layer 500 and the dielectric material layer 502 and between the dielectric material layer 506 and the dielectric material layer 502. The material of the stop layer 508 is, for example, silicon carbonitride or silicon nitride. In the capacitor structure 50 of FIG. 6, the bottom surface S2 of the conductive layer 116 may be the same height as the bottom surface S1 of the conductive layer 112.

Moreover, the same components in the capacitor structure 50 and the capacitor structure 10 are denoted by the same reference symbols, the same or similar content in the capacitor structure 50 and the capacitor structure 10 may refer to the description of the capacitor structure 10 in the foregoing embodiments, and the description thereof is omitted.

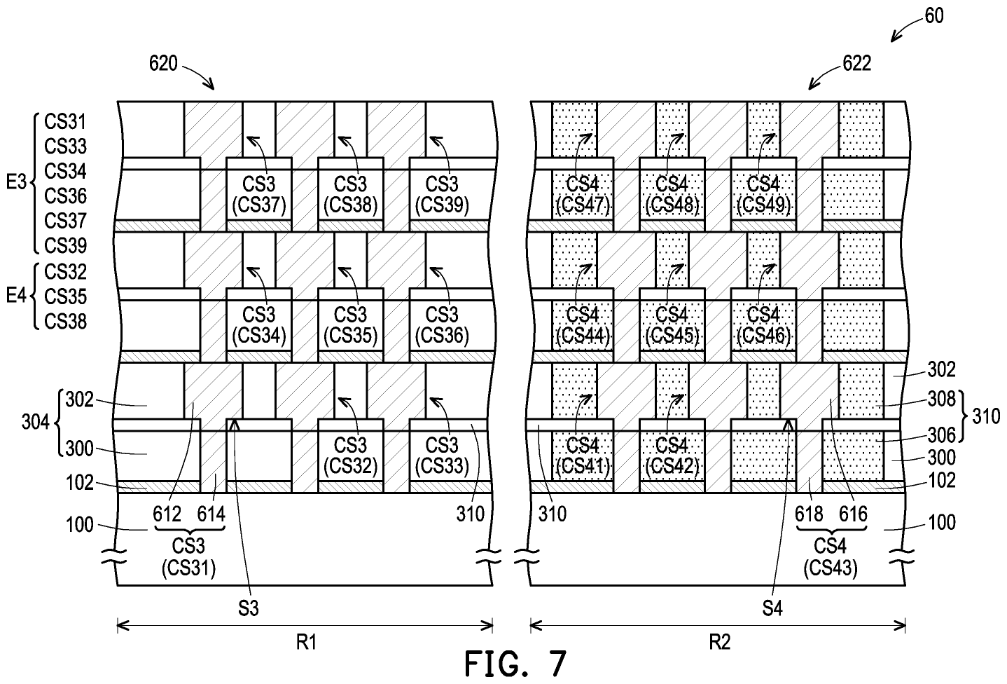

FIG. 7 is a cross-sectional view illustrating a capacitor structure according to another embodiments of the invention.

Referring to FIG. 4 and FIG. 7, the difference between the capacitor structure 60 in FIG. 7 and the capacitor structure 30 in FIG. 4 is as follows. In the embodiment of FIG. 7, the conductive structure CS3 and the conductive structure CS4 are formed by the single damascene process, and each of the conductive structure CS3 and the conductive structure CS4 may include the single damascene structure. In detail, each of the conductive layer 612 and the conductive via 614 in the conductive structure CS3 may be a single damascene structure formed by a single damascene process, and each of the conductive layer 616 and the conductive via 618 in the conductive structure CS4 may be a single damascene structure formed by a single damascene process. That is, the conductive layer 612 and the conductive via 614 in the conductive structure CS3 may be components independent of each other, and the conductive layer 616 and the conductive via 618 in the conductive structure CS4 may be components independent of each other. In addition, the bottom surface S4 of the conductive layer 616 may be the same height as the bottom surface S3 of the conductive layer 612.

In FIG. 7, the capacitor 620 includes two electrodes (e.g., the electrode E3 and the electrode E4) electrically insulated from each other. In addition, the capacitor 620 may further include the dielectric layer 304 located between the electrode E3 and the electrode E4. Each of the electrode E3 and the electrode E4 may include at least one conductive structure CS3. For example, the electrode E3 may include the conductive structure CS31, the conductive structure CS33, the conductive structure CS34, the conductive structure CS36, the conductive structure CS37, and the conductive structure CS39 electrically connected to each other, and the electrode E4 may include the conductive structure CS32, the conductive structure CS35, and the conductive structure CS38 electrically connected to each other, but the invention is not limited thereto.

In FIG. 7, the interconnect structure 622 may include at least one conductive structure CS4. The interconnect structure 622 may include a plurality of the conductive structures CS4 electrically connected to each other, but the invention is not limited thereto. For example, the conductive structure CS41, the conductive structure CS44, and the conductive structure CS47 may be electrically connected to each other and may be electrically connected to the corresponding semiconductor device and/or voltage source. The conductive structure CS42, the conductive structure CS45, and the conductive structure CS48 may be electrically connected to each other and may be electrically connected to the corresponding semiconductor device and/or voltage source. The conductive structure CS43, the conductive structure CS46, and the conductive structure CS49 may be electrically connected to each other and may be electrically connected to the corresponding semiconductor device and/or voltage source.

Moreover, the same components in the capacitor structure 60 and the capacitor structure 30 are denoted by the same reference symbols, the same or similar content in the capacitor structure 60 and the capacitor structure 30 may refer to the description of the capacitor structure 30 in the foregoing embodiments, and the description thereof is omitted.

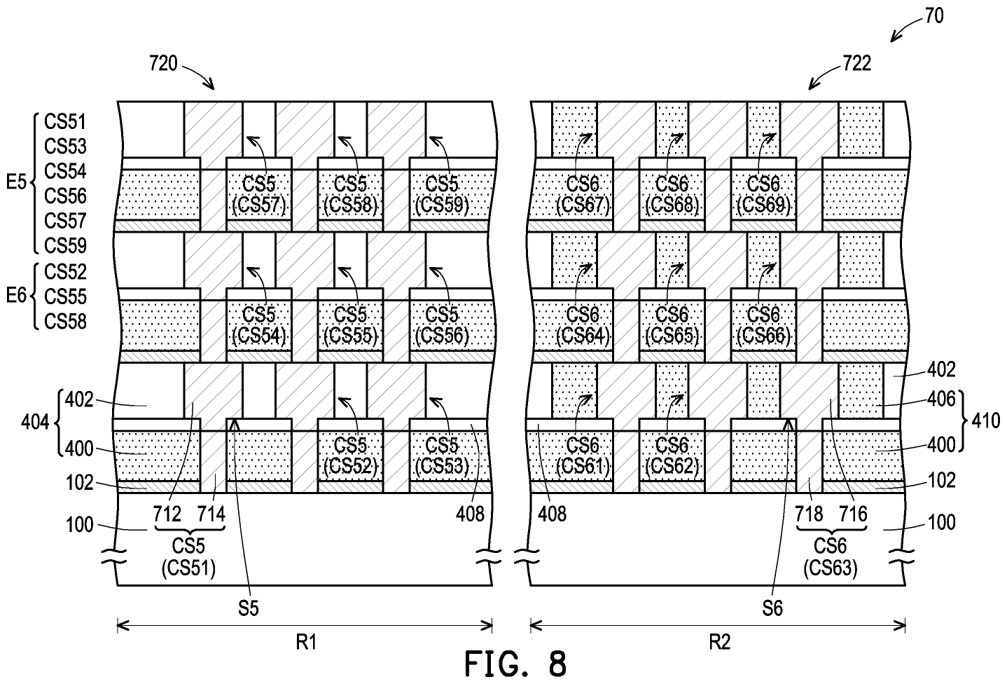

FIG. 8 is a cross-sectional view illustrating a capacitor structure according to another embodiments of the invention.

Referring to FIG. 5 and FIG. 8, the difference between the capacitor structure 70 in FIG. 8 and the capacitor structure 40 in FIG. 5 is as follows. In the embodiment of FIG. 8, the conductive structure CS5 and the conductive structure CS6 are formed by the single damascene process, and each of the conductive structure CS5 and the conductive structure CS6 may include the single damascene structure. In detail, each of the conductive layer 712 and the conductive via 714 in the conductive structure CS5 may be a single damascene structure formed by a single damascene process, and each of the conductive layer 716 and the conductive via 718 in the conductive structure CS6 may be a single damascene structure formed by a single damascene process. That is, the conductive layer 712 and the conductive via 714 in the conductive structure CS5 may be components independent of each other, and the conductive layer 716 and the conductive via 718 in the conductive structure CS6 may be components independent of each other. In addition, the bottom surface S6 of the conductive layer 716 may be the same height as the bottom surface S5 of the conductive layer 712.

In FIG. 8, the capacitor 720 includes two electrodes (e.g., the electrode E5 and the electrode E6) electrically insulated from each other. In addition, the capacitor 720 may further include the dielectric layer 404 located between the electrode E5 and the electrode E6. Each of the electrode E5 and the electrode E6 may include at least one conductive structure CS5. For example, the electrode E5 may include the conductive structure CS51, the conductive structure CS53, the conductive structure CS54, the conductive structure CS56, the conductive structure CS57, and the conductive structure CS59 electrically connected to each other, and the electrode E6 may include the conductive structure CS52, the conductive structure CS55, and the conductive structure CS58 electrically connected to each other, but the invention is not limited thereto.

In FIG. 8, the interconnect structure 722 may include at least one conductive structure CS6. The interconnect structure 722 may include a plurality of the conductive structures CS6 electrically connected to each other, but the invention is not limited thereto. For example, the conductive structure CS61, the conductive structure CS64, and the conductive structure CS67 may be electrically connected to each other and may be electrically connected to the corresponding semiconductor device and/or voltage source. The conductive structure CS62, the conductive structure CS65, and the conductive structure CS68 may be electrically connected to each other and may be electrically connected to the corresponding semiconductor device and/or voltage source. The conductive structure CS63, the conductive structure CS66, and the conductive structure CS69 may be electrically connected to each other and may be electrically connected to the corresponding semiconductor device and/or voltage source.

Moreover, the same components in the capacitor structure 70 and the capacitor structure 40 are denoted by the same reference symbols, the same or similar content in the capacitor structure 70 and the capacitor structure 40 may refer to the description of the capacitor structure 40 in the foregoing embodiments, and the description thereof is omitted.

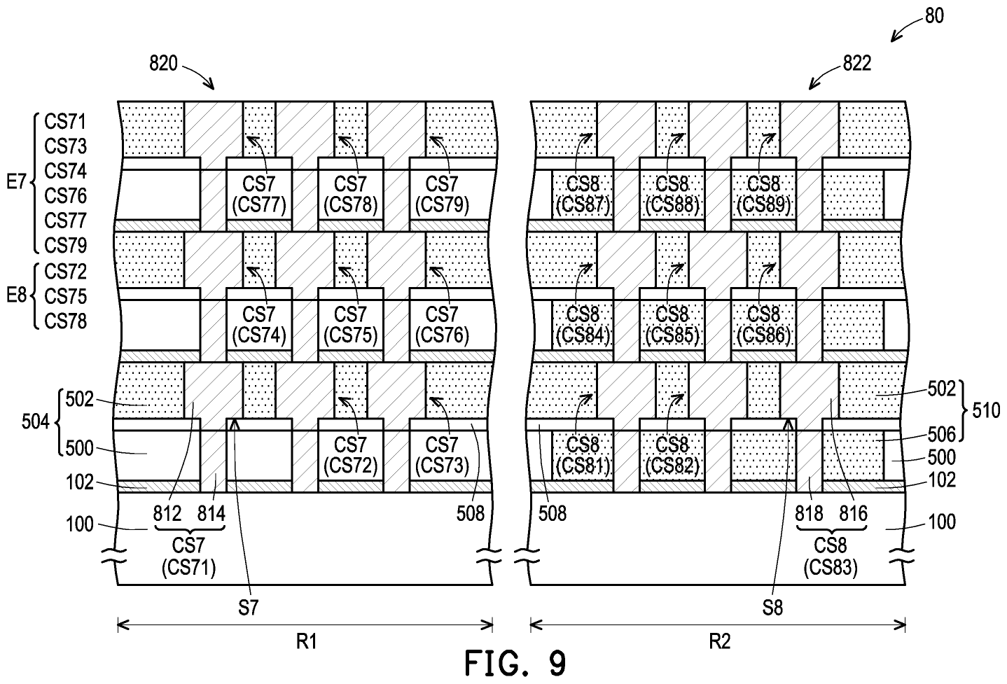

FIG. 9 is a cross-sectional view illustrating a capacitor structure according to another embodiments of the invention.

Referring to FIG. 6 and FIG. 9, the difference between the capacitor structure 80 in FIG. 9 and the capacitor structure 50 in FIG. 6 is as follows. In the embodiment of FIG. 9, the conductive structure CS7 and the conductive structure CS8 are formed by the single damascene process, and each of the conductive structure CS7 and the conductive structure CS8 may include the single damascene structure. In detail, each of the conductive layer 812 and the conductive via 814 in the conductive structure CS7 may be a single damascene structure formed by a single damascene process, and each of the conductive layer 816 and the conductive via 818 in the conductive structure CS8 may be a single damascene structure formed by a single damascene process. That is, the conductive layer 812 and the conductive via 814 in the conductive structure CS7 may be components independent of each other, and the conductive layer 816 and the conductive via 818 in the conductive structure CS8 may be components independent of each other. In addition, the bottom surface S8 of the conductive layer 816 may be the same height as the bottom surface S7 of the conductive layer 812.

In FIG. 9, the capacitor 820 includes two electrodes (e.g., the electrode E7 and the electrode E8) electrically insulated from each other. In addition, the capacitor 820 may further include the dielectric layer 504 located between the electrode E7 and the electrode E8. Each of the electrode E7 and the electrode E8 may include at least one conductive structure CS7. For example, the electrode E7 may include the conductive structure CS71, the conductive structure CS73, the conductive structure CS74, the conductive structure CS76, the conductive structure CS77, and the conductive structure CS79 electrically connected to each other, and the electrode E8 may include the conductive structure CS72, the conductive structure CS75, and the conductive structure CS78 electrically connected to each other, but the invention is not limited thereto.

In FIG. 9, the interconnect structure 822 may include at least one conductive structure CS8. In the present embodiment, the interconnect structure 822 may include a plurality of the conductive structures CS8 electrically connected to each other, but the invention is not limited thereto. For example, the conductive structure CS81, the conductive structure CS84, and the conductive structure CS87 may be electrically connected to each other and may be electrically connected to the corresponding semiconductor device and/or voltage source. The conductive structure CS82, the conductive structure CS85, and the conductive structure CS88 may be electrically connected to each other and may be electrically connected to the corresponding semiconductor device and/or voltage source. The conductive structure CS83, the conductive structure CS86, and the conductive structure CS89 may be electrically connected to each other and may be electrically connected to the corresponding semiconductor device and/or voltage source.

Moreover, the same components in the capacitor structure 80 and the capacitor structure 50 are denoted by the same reference symbols, the same or similar content in the capacitor structure 80 and the capacitor structure 50 may refer to the description of the capacitor structure 50 in the foregoing embodiments, and the description thereof is omitted.

In summary, in the capacitor structure and the manufacturing method thereof of the aforementioned embodiments, since at least a portion of the dielectric layer in the capacitor region has a higher dielectric constant, the capacitance value of the capacitor in the capacitor region can be increased, thereby reducing the area of the capacitor. In addition, since the dielectric layer in the non-capacitor region has a lower dielectric constant, the parasitic capacitance can be reduced, thereby reducing the RC delay in the non-capacitor region.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A capacitor structure, comprising:
a substrate comprising a capacitor region and a non-capacitor region;
at least one first dielectric layer located on the substrate in the capacitor region and the non-capacitor region;
at least one second dielectric layer located on the substrate in the non-capacitor region, wherein at least a portion of the second dielectric layer is located in the first dielectric layer, a material of the second dielectric layer is different from a material of at least a portion of the first dielectric layer, and a dielectric constant of the second dielectric layer is smaller than a dielectric constant of at least a portion of the first dielectric layer;
a capacitor located in the at least one first dielectric layer in the capacitor region and comprising two electrodes electrically insulated from each other; and
an interconnect structure located in the at least one second dielectric layer in the non-capacitor region.

2. The capacitor structure according to claim 1, wherein the material of the second dielectric layer is completely different from the material of the first dielectric layer.

3. The capacitor structure according to claim 1, wherein the dielectric constant of the second dielectric layer is smaller than the dielectric constant of the entire first dielectric layer.

4. The capacitor structure according to claim 1, wherein the entire second dielectric layer is located in the first dielectric layer.

5. The capacitor structure according to claim 1, wherein
the electrode comprises at least one first conductive structure,
the first conductive structure comprises a first conductive layer,
the interconnect structure comprises at least one second conductive structure, and
the second conductive structure comprises a second conductive layer.

6. The capacitor structure according to claim 5, wherein each of the first conductive structure and the second conductive structure comprises a dual damascene structure or a single damascene structure.

7. The capacitor structure according to claim 5, wherein a bottom surface of the second conductive layer is lower than a bottom surface of the first conductive layer.

8. The capacitor structure according to claim 5, wherein a bottom surface of the second conductive layer is the same height as a bottom surface of the first conductive layer.

9. The capacitor structure according to claim 5, wherein
the first conductive structure further comprises a first conductive via,
the first conductive via is located under the first conductive layer and is electrically connected to the first conductive layer,
the second conductive structure further comprises a second conductive via, and
the second conductive via is located under the second conductive layer and is electrically connected to the second conductive layer.

10. The capacitor structure according to claim 9, wherein the first conductive layer and the first conductive via are integrally formed, and the second conductive layer and the second conductive via are integrally formed.

11. The capacitor structure according to claim 9, wherein the first conductive layer and the first conductive via are components independent of each other, and the second conductive layer and the second conductive via are components independent of each other.

12. The capacitor structure according to claim 9, wherein each of the first dielectric layer and the second dielectric layer comprises a single-layer structure.

13. The capacitor structure according to claim 9, wherein each of the first dielectric layer and the second dielectric layer comprises a multilayer structure.

14. The capacitor structure according to claim 13, wherein
the first dielectric layer comprises:
a first dielectric material layer, wherein the first conductive via is located in the first dielectric material layer; and
a second dielectric material layer located on the first dielectric material layer, wherein the first conductive layer is located in the second dielectric material layer, and
the second dielectric layer comprises:
a third dielectric material layer, wherein the third dielectric material layer is located in the first dielectric material layer, and the second conductive via is located in the third dielectric material layer; and
a fourth dielectric material layer located on the third dielectric material layer, wherein the fourth dielectric material layer is located in the second dielectric material layer, and the second conductive layer is located in the fourth dielectric material layer.

15. The capacitor structure according to claim 13, wherein
the first dielectric layer comprises:
a first dielectric material layer, wherein the first conductive via is located in the first dielectric material layer; and
a second dielectric material layer located on the first dielectric material layer, wherein the first conductive layer is located in the second dielectric material layer, and
the second dielectric layer comprises:
the first dielectric material layer, wherein the second conductive via is located in the first dielectric material layer; and
a third dielectric material layer located on the first dielectric material layer, wherein the third dielectric material layer is located in the second dielectric material layer, and the second conductive layer is located in the third dielectric material layer.

16. The capacitor structure according to claim 13, wherein
the first dielectric layer comprises:
a first dielectric material layer, wherein the first conductive via is located in the first dielectric material layer; and
a second dielectric material layer located on the first dielectric material layer, wherein the first conductive layer is located in the second dielectric material layer, and
the second dielectric layer comprises:
a third dielectric material layer, wherein the third dielectric material layer is located in the first dielectric material layer, and the second conductive via is located in the third dielectric material layer; and
the second dielectric material layer is located on the third dielectric material layer, and the second conductive layer is located in the second dielectric material layer.

17. The capacitor structure according to claim 5, wherein the electrode comprises a plurality of the first conductive structures electrically connected to each other, and the interconnect structure comprises a plurality of the second conductive structures electrically connected to each other.

18. A manufacturing method of a capacitor structure, comprising:
providing a substrate, wherein the substrate comprises a capacitor region and a non-capacitor region;
forming at least one first dielectric layer on the substrate in the capacitor region and the non-capacitor region;
forming at least one second dielectric layer on the substrate in the non-capacitor region, wherein at least a portion of the second dielectric layer is located in the first dielectric layer, a material of the second dielectric layer is different from a material of at least a portion of the first dielectric layer, and a dielectric constant of the second dielectric layer is smaller than a dielectric constant of at least a portion of the first dielectric layer;
forming a capacitor in the at least one first dielectric layer in the capacitor region, wherein the capacitor comprises two electrodes electrically insulated from each other; and
forming an interconnect structure in the at least one second dielectric layer in the non-capacitor region.

19. The manufacturing method of the capacitor structure according to claim 18, wherein the electrode comprises at least one first conductive structure, the interconnect structure comprises at least one second conductive structure, and a method of forming the first conductive structure and the second conductive structure comprises:
forming the first dielectric layer on the substrate;
forming an opening in the first dielectric layer;
forming a dielectric material layer filling up the opening;
removing the dielectric material layer located outside the opening to form the second dielectric layer; and
forming the first conductive structure in the first dielectric layer and forming the second conductive structure in the second dielectric layer by a damascene process.

20. The manufacturing method of the capacitor structure according to claim 19, wherein the damascene process comprises a dual damascene process or a single damascene process.
